(19) United States
(12) Patent Application Publication
(10) Pub. No.: US 2025/0113522 A1
(43) Pub. Date: Apr. 3, 2025

(54) 3D Memory Mold Film Stack

(71) Applicant: Applied Materials, Inc., Santa Clara, CA (US)

(72) Inventors: Ruiying HAO, Santa Clara, CA (US); Fredrick David FISHBURN, Aptos, CA (US); Raghuveer Satya MAKALA, Campbell, CA (US); Thomas John KIRSCHENHEITER, Tempe, AZ (US); Balasubramanian PRANATHARTHIHARAN, San Jose, CA (US)

(21) Appl. No.: 18/899,327

(22) Filed: Sep. 27, 2024

Related U.S. Application Data
(60) Provisional application No. 63/541,368, filed on Sep. 29, 2023.

(51) Int. Cl. H01L 29/775; H01L 21/02; H01L 29/423; H01L 29/66; H01L 29/786

(52) U.S. Cl. CPC H10D 30/43; H01L 21/02532; H10D 30/014; H10D 30/6757; H10D 30/6735

(57) ABSTRACT

Three-dimensional (3D) memory structures and methods of formation of same are provided herein. In some embodiments, a 3D memory fabrication structure includes: a base silicon (Si) layer; a silicon germanium (SiGe) layer disposed above the base Si layer; and a doped silicon (Si) layer disposed on at least one side of the SiGe layer, wherein the doped Si layer contains a dopant that is at least one of carbon (C) or boron (B).

### CROSS-REFERENCE TO RELATED APPLICATIONS

This application claims benefit of U.S. provisional patent application Ser. No. 63/541,368, filed Sep. 29, 2023, which is herein incorporated by reference in its entirety.

### FIELD

Embodiments of the present principles generally relate to semiconductor manufacturing.

### BACKGROUND

The storage and retrieval of data has been a limiting factor for many aspects of the computing industry. Memory devices can easily throttle the overall performance of modern computing devices. To make memory faster, memory structures have been scaled down to miniscule sizes, dramatically increasing the density of the memory structures. Three-dimensional memory structures, such as three-dimensional dynamic random-access memory (3D DRAM) or other memory structures, may be used to further increase memory densities. In some three-dimensional memory structures, alternate layers of Si and SiGe are grown epitaxially from crystal silicon substrate. However, the inventors have observed that there is a strain induced from the mismatch in lattice between Si and Ge which can undesirably result in deformation, or bowing, of the substrate.

Accordingly, the inventors have provided Si/SiGe three-dimensional memory structures, and methods of making the same, that reduce or eliminate substrate bowing.

### SUMMARY

Three-dimensional (3D) memory structures, as well as methods and apparatus for forming such structures, are provided herein.

In some embodiments, a 3D memory fabrication structure includes: a base silicon (Si) layer; a silicon germanium (SiGe) layer disposed above the base Si layer; and a doped silicon (Si) layer disposed on at least one side of the SiGe layer, wherein the doped Si layer contains a dopant that is at least one of carbon (C) or boron (B). In some embodiments, a 3D memory fabrication structure includes: a base silicon (Si) layer; a silicon germanium (SiGe) layer disposed above the base Si layer; and a doped silicon (Si) layer abutting one side of the SiGe layer, wherein the doped Si layer contains a dopant that is at least one of carbon (C) or boron (B). In some embodiments, one or more of the base Si layer and the SiGe layer is undoped. In some embodiments, the SiGe layer includes about 10-25 atomic percent germanium. In some embodiments, the doped Si layer contains about 0.1-2 atomic percent of the dopant. In some embodiments, the amount of dopant in the doped Si layer varies from a bottom of the doped Si layer to a top of the doped Si layer. In some embodiments, the SiGe layer has a thickness less than a thickness of the doped Si layer and the thickness of the doped Si layer is less than a thickness of the base Si layer. In some embodiments, the doped Si layer is disposed atop the base Si layer, the SiGe layer is disposed atop the doped Si layer, and further comprising a second doped Si layer disposed atop the SiGe layer. In some embodiments, the doped Si layer is disposed atop the base Si layer and the SiGe layer is disposed atop the doped Si layer. In some embodiments, the SiGe layer is disposed atop the base Si layer and the doped Si layer is disposed atop the SiGe layer. In some embodiments, the base Si layer, the SiGe layer, and the doped Si layer are part of a repeating film stack, wherein the film stack is repeatedly deposited one atop the other a plurality of times.

In some embodiments, a method of forming a three-dimensional (3D) memory structure includes: forming a film stack on a substrate by: depositing a base silicon (Si) layer atop the substrate; depositing a doped Si layer atop the base Si layer, wherein the doped Si layer includes a dopant that is at least one of carbon or boron; and depositing a silicon germanium (SiGe) layer atop the base Si layer. In some embodiments, the doped Si layer is deposited atop the SiGe layer. In some embodiments, the doped Si layer is deposited between the base Si layer and the SiGe layer. In some embodiments, the doped Si layer is a first doped Si layer deposited between the base Si layer and the SiGe layer and further comprising depositing a second doped Si atop the SiGe layer. In some embodiments, the film stack is repeatedly deposited one atop the other a plurality of times.

In some embodiments, apparatus and systems are provided for forming a three-dimensional (3D) memory structure in accordance with any of the embodiments disclosed herein.

In some embodiments, a non-transitory computer readable medium is provided, having instructions formed thereon that, when executed, cause a process chamber to perform any of the methods for forming 3D memory structures as described herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a three-dimensional (3D) memory structure in accordance with at least some embodiments of the present disclosure.

FIG. 2 depicts a schematic side view of a 3D memory structure in accordance with at least some embodiments of the present disclosure.

FIG. 3 depicts a schematic side view of a 3D memory structure in accordance with at least some embodiments of the present disclosure.

FIG. 4 is a flow chart depicting a method of forming a 3D memory structure in accordance with at least some embodiments of the present disclosure.

FIG. 5 is a schematic diagram of an apparatus for processing a substrate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures provided herein enable production of three-dimensional (3D memory structures, or film stacks. For example, the methods and structures provided herein enable production of 3D memory cells that include gate-all-around (GAA) structures around crystalline silicon (c-Si) channels. For example, embodiments of the present disclosure provide improved enabling structures suitable for further use in the fabrication of or as part of a process sequence for the fabrication of 3D memory cells, such as for example, dynamic random access memory (DRAM), NAND memory, or the like. The three-dimensional memory structures provided herein advantageously reduce or eliminate wafer bowing and defectivity observed in some other three-dimensional memory structures.

FIGS. 1-3 respectively depict schematic side views of 3D memory structures in accordance with at least some embodiments of the present disclosure. Similar elements in the Figures have the same reference numeral and descriptions thereof are not repeated.

FIG. 1 depicts a schematic side view of a 3D memory structure formed on a substrate 100. The substrate 100 can be any suitable substrate used in 3D memory fabrication, such as a semiconductor wafer or the like and can further include one or more layers and/or structures upon which the 3D memory structure is formed. In some embodiments, the 3D memory structure includes a film stack 110 that can be repeatedly formed atop each other a plurality of times, such as tens of times, hundreds of times, or the like. As used herein, a “layer” refers to a single crystalline layer of material as well as multiple crystalline layers of the same material which in combination form a single crystalline layer.

The film stack 110 includes a base silicon (Si) layer 102, a doped Si layer 104 (e.g., a first doped Si layer), a silicon germanium (SiGe) layer 106, and a doped Si layer 108 (e.g., a second doped Si layer).

The base Si layer 102 is configured to function as the channel for the 3D memory structure upon completion of fabrication. In some embodiments, the base Si layer 102 is an undoped Si layer and can be formed by suitable deposition process such as epitaxial deposition. In some embodiments, the base Si layer 102 is formed to a thickness of less than about 50 nm, such as about 10-60 nm.

In some embodiments, the doped Si layer 104 is deposited atop, such as directly atop, the base Si layer 102. The doped Si layer 104 can be formed by suitable deposition process such as epitaxial deposition. In some embodiments, the doped Si layer 104 can be formed to a thickness of about 10-100 nm. The dopant in the doped Si layer 104 can be carbon, boron, or both carbon and boron. The dopant concentration in the doped Si layer 104 can be substantially uniform or constant, or the dopant concentration can vary. For example, the dopant concentration can vary from a lower amount (e.g., zero or some other lower than nominal amount) near the beginning of the deposition process to a higher amount as the film deposition process continues. In some embodiments, the dopant concentration can vary from a lower amount (e.g., zero or some other lower than nominal amount) near the beginning of the deposition process to a higher amount as the film deposition process continues through a middle region of the layer, and then decrease again to a lower amount (e.g., zero or some other lower than nominal amount) near the end of the deposition process. The varying of the dopant concentration can be continuous or stepwise.

The inventors have observed that If the dopant concentration in the doped Si layer is too low, it does not help reduce the compressive stress due to SiGe films to a desirable level, and if the dopant concentration in the doped Si layer is too high, it leads to epitaxial defectivity. Accordingly, in some embodiments, the dopant concentration can be from about 0.1 to about 2 atomic percent. The inventors have observed that providing a dopant concentration in that range advantageously reduces compressive stress, leading to reduction or elimination of substrate bowing and/or defectivity issues, while maintaining a similar selectivity to silicon during subsequent silicon germanium etching processes performed downstream in the 3D memory fabrication process. The inventors have further observed that a lower concentration of the dopant in the doped Si layer 104 advantageously minimizes any negative impact of dopant migration or diffusion into the base Si layer 102 (e.g., into the Si channel of the final device).

In some embodiments, the SiGe layer 106 is deposited atop, such as directly atop, the doped Si layer 104. In some embodiments, the SiGe layer 106 is an undoped SiGe layer and can be formed by suitable deposition process such as epitaxial deposition. In some embodiments, the SiGe layer 106 is formed to a thickness of about 5-20 nm. In some embodiments the SiGe layer 106 includes about 10-25 atomic percent Ge. The SiGe layer 106 is a sacrificial layer in the 3D memory fabrication sequence and is subsequently removed in a downstream etch process. The inventors have observed that a SiGe layer 106 having the Ge concentration described above retains a good etch rate and selectivity to both Si and C and/or B doped Si (e.g., to the base Si layer 102 and to the doped Si layer 104).

In some embodiments, the doped Si layer 108 (e.g., a second doped Si layer) is deposited atop, such as directly atop, the SiGe layer 106. The doped Si layer 108 can be formed by suitable deposition process such as epitaxial deposition. In some embodiments, the doped Si layer 108 can be formed to a thickness of about 10-100 nm. The dopant in the doped Si layer 108 can be carbon, boron, or both carbon and boron. The dopant concentration in the doped Si layer 108 can be substantially uniform or constant, or the dopant concentration can vary in the same manner as described above with respect to the doped Si layer 104. For similar reasons as described above with respect to the doped Si layer 104, in some embodiments, the dopant concentration in the doped Si layer 108 can be from about 0.1 to about 2 atomic percent. In some embodiments, the doped Si layer 104 and the doped Si layer 108 can be substantially identical to each other in any or all of dopant, dopant concentration, dopant concentration gradient, or thickness. In some embodiments, the doped Si layer 104 and the doped Si layer 108 can be different than each other in any or all of dopant, dopant concentration, dopant concentration gradient, or thickness.

In some embodiments, a transition layer 112 can be formed between one or more of the various layers of the film stack 110, as indicated by dashed lines. For example, when depositing the various layers in an epitaxial deposition process, as the gas sources for the various dopants or elements other than Si are controlled (e.g., turned on or off, ramped up or down, etc.), an interfacial layer (e.g., transition layer) can be formed having a composition that varies from that of the underlying layer upon which the subsequent layer is being formed to that of the subsequent layer. For example, when depositing the doped Si layer 104 atop the base Si layer 102, a transition layer 112 can be formed when introducing a dopant precursor in the deposition process. Similarly, when ending the deposition of the doped Si layer 104 and beginning the deposition of the SiGe layer 106, a transition layer 112 can be formed between ceasing flow of the dopant precursor and introducing the germanium precursor in the deposition process. Moreover, a time period can exist between ceasing the flow of the dopant precursor and introducing flow of the germanium precursor, during which time a Si layer can be formed having little to no dopant and little to no germanium (e.g., a transition Si layer). The transition layer 112 can exist between any two adjacent layers, including all adjacent layers in the film stack 110. However, the transition layer 112 need not exist between all adjacent layers of the film stack 110. In some embodiments, transition layers 112 are formed between the doped silicon layer(s) and the SiGe layer. Each transition layer 112 can generally have a thickness of up to about 10 nm.

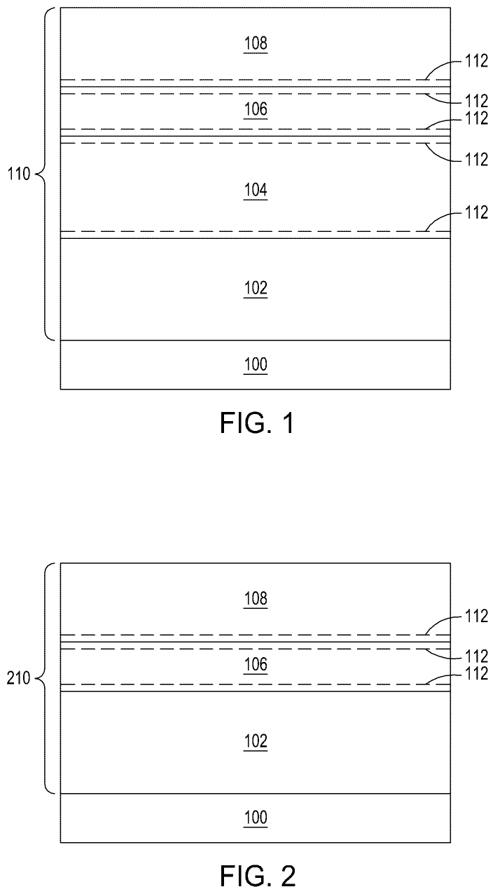

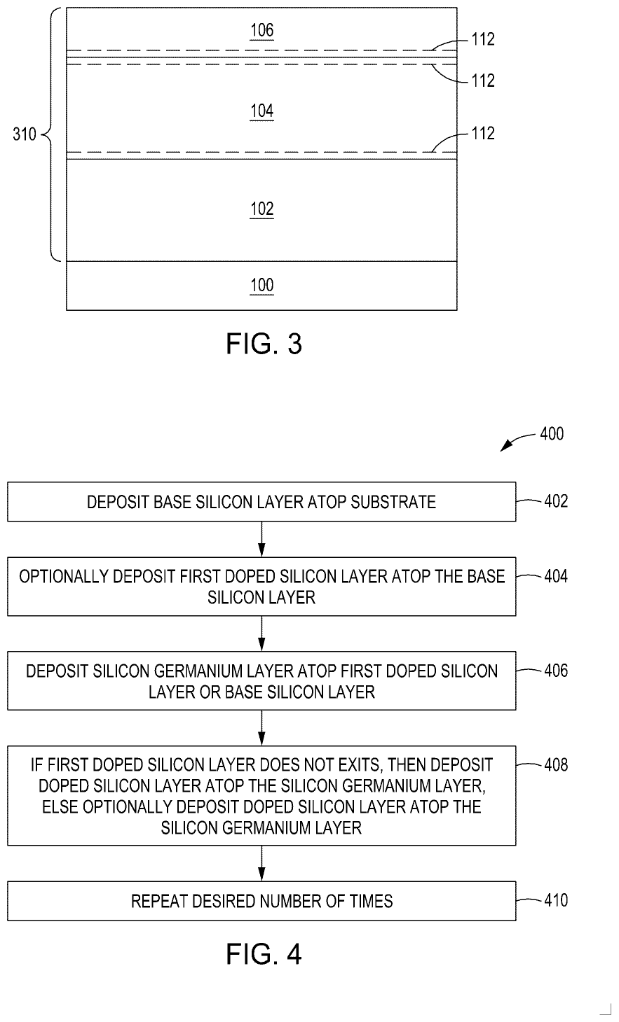

In some embodiments, only one of the doped Si layer 104 or the doped Si layer 108 is provided. For example, in some embodiments and as depicted in FIG. 2, the doped Si layer 104 is omitted in film stack 210 where the SiGe layer 106 is deposited atop, such as directly atop, the base Si layer 102 (with or without transition layer 112). Alternatively, in some embodiments and as depicted in FIG. 3, the doped Si layer 108 is omitted in film stack 310 where the SiGe layer 106 is the uppermost layer in the film stack 310.

In some embodiments, the total thickness of the film stack 110, 210, 310 is about 80 nm, such as between about 50 and 100 nm. In some embodiments, the thickness of the base Si layer 102 can be set by taking a desired total unit thickness of the film stack 110, 210, 310 and subtracting the thickness of the SiGe layer, the doped Si layer(s), and any transition layers 112.

Although only one film stack 110, 210, 310 is illustratively shown in FIGS. 1-3, each film stack 110, 210, 310 is repeated a plurality of times (e.g., a second film stack is formed directly on the first film stack, a third film stack is formed on the second film stack, etc.) to form a structure suitable for further processing to for 3D memory devices. For example, in a typical 3D memory structure, the film stack 110, 210, 310 may be repeated about 100 or more times. The inventors have observed that forming such structures with a repeating film stack 110, 210, 310 as described herein advantageously maintains acceptable substrate bow and low stress providing good (e.g., low) epitaxial defectivity. Moreover, such structures utilizing the repeating film stack 110, 210, 310 described herein advantageously support subsequent processing steps required to ultimately form 3D memory devices.

FIG. 4 is a flow chart depicting a method 400 of forming a 3D memory structure in accordance with at least some embodiments of the present disclosure, such as by a heteroepitaxy process including chemical vapor deposition or other known deposition techniques. The method 400 is suitable for use in fabricating the structures described above with respect to FIGS. 1-3, which respectively depict schematic side views of various embodiments of the present disclosure.

The method 400 generally begins at block 402, where base Si layer 102 is deposited atop a substrate 100 (see, e.g., FIGS. 1-3). The base Si layer may be formed by any suitable process, such as chemical vapor deposition (CVD), in a suitable process chamber, such as an RP EPI chamber, commercially available from Applied Materials, Inc. of Santa Clara, CA.

Next, at block 404, doped Si layer 104 (e.g., a first doped Si layer) may be deposited atop the base Si layer (see, e.g., FIGS. 1 and 3). The first doped Si layer may be formed by any suitable process, such as chemical vapor deposition (CVD) and may be formed in the same chamber as the base Si layer. In some embodiments, the first doped Si layer is deposited directly atop the base Si layer. In some embodiments, the first doped Si layer is deposited directly atop a transition layer (e.g., transition layer 112) that is deposited directly atop the base Si layer.

Next, at block 406, SiGe layer 106 is deposited atop the first doped Si layer (see, e.g., FIGS. 1 and 3) or atop the base Si layer (see, e.g., FIG. 2). The SiGe layer may be formed by any suitable process, such as chemical vapor deposition (CVD) and may be formed in the same chamber as the base Si layer and, when present, the first doped Si layer. In some embodiments, the SiGe layer is deposited directly atop the underlying layer noted above (e.g., the Si base layer or the first doped Si layer). In some embodiments, the SiGe layer is deposited directly atop a transition layer (e.g., transition layer 112) that is deposited directly atop one or more of the first doped Si layer or the base Si layer.

Next, at block 408, if the first doped Si layer does not exist (e.g., was not deposited at optional block 404), then doped Si layer 108 may be deposited atop the SiGe layer to form film stack 210 (see, e.g., FIG. 2). If the first doped Si layer does exist (e.g., was deposited at optional block 404), then, the doped Si layer 108 can optionally be deposited atop the SiGe layer. For example, in embodiments corresponding to FIG. 1, the doped Si layer 104 is a first doped Si layer (deposited atop the base Si layer), the doped Si layer 108 is a second doped Si layer (deposited atop the SiGe layer), and the deposited layers define film stack 110. In embodiments corresponding to FIG. 3, the doped Si layer 108 is not deposited and the first doped Si layer (e.g., doped Si layer 104) is the only doped Si layer in film stack 310.

The second doped Si layer may be formed by any suitable process, such as chemical vapor deposition (CVD) and may be formed in the same chamber as the base Si layer, the first doped Si layer (when present), and the SiGe layer. In some embodiments, the doped Si layer is deposited directly atop the SiGe layer. In some embodiments, the doped Si layer is deposited directly atop a transition layer (e.g., transition layer 112) that is deposited directly atop the SiGe layer. In all embodiments, any transition layers formed are part of the defined film stack (e.g., film stack 110, 210, 310).

Next, at block 410, blocks 402-408 can be repeated to form one or more additional film stacks atop the initial film stack. For example, a repeated block 402 can be performed to deposit a second base Si layer atop the doped Si layer (when present, e.g., FIGS. 1 and 2) or atop the SiGe layer (e.g., FIG. 3), and so on. The repeated deposition of the film stacks can continue to form as many repeated film stacks as is needed for a particular memory structure or structures, allowing tremendous flexibility for memory structure design. Repeated film stacks can be the same as a prior deposited film stack, or can be different than the prior deposited film stack in terms of dopant concentrations, gradients, transition layers, or the like. For example, generally speaking, each film stack (e.g., film stack 110, 210, 310) in a plurality of film stacks comprising the 3D memory structure can independently be any of the embodiments of the film stacks described above, including a plurality of identical film stacks, a plurality of film stacks each having a unique configuration, or a plurality of film stacks having two or more different film stack configurations.

Upon completion of the desired number of repetitive cycles at 410, the method 400 generally ends. However, the resultant structures depicted in FIGS. 1-3 may advantageously be further processed to continue fabrication of a 3D memory device with reduced stress-induced defects as compared to conventional 3D memory devices.

The method 400 described above may be performed in a process chamber configured for epitaxial deposition, such as the RP EPI chamber noted above or other similar chamber. The process chamber can be a standalone process chamber or part of an integrated tool (or a cluster tool) including suitable process chambers configured at least for chemical vapor deposition (CVD).

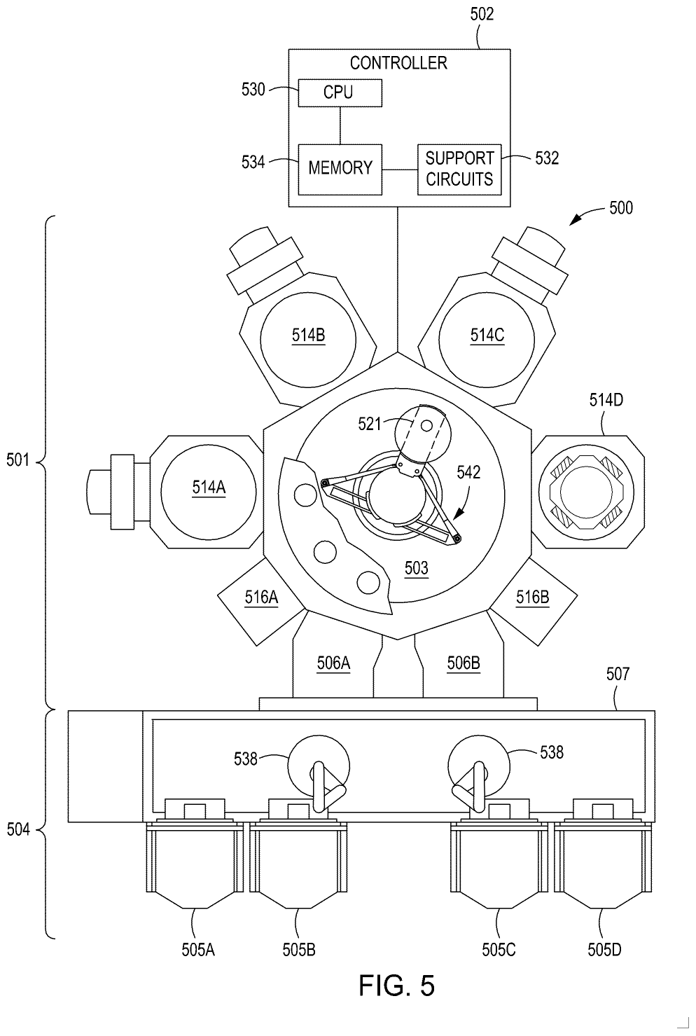

For example, an integrated tool (e.g., tool 500) described below with respect to FIG. 5 facilitates operation of the methods described herein such that there are limited or no vacuum breaks between processes. Reduced vacuum breaks may limit or prevent contamination (e.g., oxidation) of portions of the substrate and may further enhance throughput by reducing the amount of time between processes and reducing or eliminating certain processes such as pre-clean operations or other operations that would otherwise be required where the process to be performed sequentially in standalone process chambers.

The tool 500 includes a vacuum-tight processing platform (processing platform 501), a factory interface 504, and a system controller (e.g., system controller 502). The processing platform 501 comprises multiple process chambers, such as for example 514A, 514B, 514C, and 514D operatively coupled to a vacuum substrate transfer chamber (transfer chamber 503). The factory interface 504 is operatively coupled to the transfer chamber 503 by one or more load lock chambers (two load lock chambers, such as 506A and 506B shown in FIG. 5).

In some embodiments, the factory interface 504 comprises at least one docking station 507, at least one factory interface robot 538 to facilitate the transfer of one or more semiconductor substrates (e.g., wafers). The docking station 507 is configured to accept one or more front opening unified pods (FOUP). Four FOUPS, such as 505A, 505B, 505C, and 505D are shown in the embodiment of FIG. 5. The factory interface robot 538 is configured to transfer the substrates from the factory interface 504 to the processing platform 501 through the load lock chambers, such as 506A and 506B. Each of the load lock chambers 506A and 506B have a first port coupled to the factory interface 504 and a second port coupled to the transfer chamber 503. The load lock chamber 506A and 506B are coupled to a pressure control system (not shown) which pumps down and vents the load lock chambers 506A and 506B to facilitate passing the substrates between the vacuum environment of the transfer chamber 503 and the substantially ambient (e.g., atmospheric) environment of the factory interface 504. The transfer chamber 503 has a vacuum robot 542 disposed within the transfer chamber 503. The vacuum robot 542 is capable of transferring substrates 521 between the load lock chamber 506A and 506B and the process chambers 514A, 514B, 514C, and 514D.

In some embodiments, the process chambers 514A, 514B, 514C, and 514D, are coupled to the transfer chamber 503. The process chambers 514A, 514B, 514C, and 514D comprise at least a CVD chamber configured for the above-described processes. Additional CVD chambers and/or other chambers may also be provided.

In some embodiments, at least one deposition chamber is provided that is configured to deposit a repeating film stack of silicon (Si) layers, doped Si layers, and silicon germanium (SiGe) layers, such as described above in any of FIGS. 1-3.

In some embodiments, one or more optional service chambers (shown as 516A and 516B) may be coupled to the transfer chamber 503. The service chambers 516A and 516B may be configured to perform other substrate processes, such as degassing, precleaning, etching, orientation, substrate metrology, preheating, cool down, and the like.

In some embodiments, the system controller 502 controls the operation of the tool 500 using a direct control of the chambers coupled to the tool or alternatively, by controlling the computers (or controllers) associated with the chambers coupled to the tool 500. In operation, the system controller 502 enables data collection and feedback from the respective chambers and systems to optimize performance of the tool 500. The system controller 502 generally includes a central processing unit (CPU) 530, a memory 534, and a support circuit 532. The CPU 530 may be any form of a general-purpose computer processor that can be used in an industrial setting. The support circuit 532 is conventionally coupled to the CPU 530 and may comprise a cache, clock circuits, input/output subsystems, power supplies, and the like. Software routines, such as processing methods as described above may be stored in the memory 534 (e.g., non-transitory computer readable storage medium) and, when executed by the CPU 530, transform the CPU 530 into a specific purpose computer (system controller 502) to cause the method 400 described above to be performed. The software routines may also be stored and/or executed by a second controller (not shown) that is located remotely from the tool 500. In some embodiments, the system controller 502 is a controller that directly controls the process chamber to perform the method 400 described above.

While the foregoing is directed to embodiments of the present disclosure, other and further embodiments of the disclosure may be devised without departing from the basic scope thereof.

1. A three-dimensional (3D) memory fabrication structure, comprising:
a base silicon (Si) layer;
a silicon germanium (SiGe) layer disposed above the base Si layer; and
a doped silicon (Si) layer disposed on at least one side of the SiGe layer, wherein the doped Si layer contains a dopant that is at least one of carbon (C) or boron (B).

2. The 3D memory fabrication structure of claim 1, wherein one or more of the base Si layer and the SiGe layer is undoped.

3. The 3D memory fabrication structure of claim 1, wherein the SiGe layer includes about 10-25 atomic percent germanium.

4. The 3D memory fabrication structure of claim 1, wherein the doped Si layer contains about 0.1-2 atomic percent of the dopant.

5. The 3D memory fabrication structure of claim 1, wherein an amount of dopant in the doped Si layer varies from a bottom of the doped Si layer to a top of the doped Si layer.

6. The 3D memory fabrication structure of claim 1, wherein the SiGe layer has a thickness less than a thickness of the doped Si layer and the thickness of the doped Si layer is less than a thickness of the base Si layer.

7. The 3D memory fabrication structure of claim 1, wherein the doped Si layer is disposed atop the base Si layer, the SiGe layer is disposed atop the doped Si layer, and further comprising a second doped Si layer disposed atop the SiGe layer.

8. The 3D memory fabrication structure of claim 1, wherein:
the doped Si layer is disposed atop the base Si layer and the SiGe layer is disposed atop the doped Si layer; or
the SiGe layer is disposed atop the base Si layer and the doped Si layer is disposed atop the SiGe layer.

9. The 3D memory fabrication structure of claim 1, wherein the doped Si layer directly abuts the SiGe layer.

10. The 3D memory fabrication structure of claim 1, further comprising a transition Si layer disposed between the SiGe layer and the doped Si layer.

11. The 3D memory fabrication structure of claim 1, wherein the base Si layer, the SiGe layer, and the doped Si layer are part of a repeating film stack, wherein the film stack is repeatedly deposited one atop the other a plurality of times with either uniform or varied dopant concentration in at least two film stacks of the repeating film stack.

12. A method of forming a three-dimensional (3D) memory structure, comprising:
forming a film stack on a substrate by:
depositing a base silicon (Si) layer atop the substrate;
depositing a doped Si layer atop the base Si layer, wherein the doped Si layer includes a dopant that is at least one of carbon or boron; and
depositing a silicon germanium (SiGe) layer atop the base Si layer.

13. The method of claim 12, wherein:
the doped Si layer is deposited atop the SiGe layer; or
the SiGe layer is deposited atop the doped Si layer.

14. The method of claim 12, wherein the doped Si layer is a first doped Si layer, the SiGe layer is deposited atop the first doped Si layer, and further comprising depositing a second doped Si layer atop the SiGe layer.

15. The method of claim 12, wherein one or more of the base Si layer and the SiGe layer is undoped.

16. The method of claim 12, wherein the SiGe layer includes about 10-25 atomic percent germanium.

17. The method of claim 12, wherein the doped Si layer contains about 0.1-2 atomic percent of the dopant.

18. The method of claim 12, wherein the SiGe layer has a thickness less than a thickness of the doped Si layer and the thickness of the doped Si layer is less than a thickness of the base Si layer.

19. The method of claim 12, wherein the film stack is repeatedly deposited one atop the other a plurality of times.

20. A non-transitory computer readable medium, having instructions formed thereon that, when executed, cause a process chamber to perform a method, the method as described in claim 1.
